(19) United States
(12) Patent Application Publication
(10) Pub. No.: US 2023/0115957 A1
(43) Pub. Date: Apr. 13, 2023

(54) SEMICONDUCTOR PACKAGES

(71) Applicant: Samsung Electronics Co., Ltd., Suwon-si (KR)

(72) Inventor: KIJU LEE, Seoul (KR)

(21) Appl. No.: 17/831,627

(22) Filed: Jun. 3, 2022

(30) Foreign Application Priority Data
Sep. 29, 2021 (KR) 10-2021-0128893

(51) Int. Cl. H01L 23/13; H01L 25/16; H01L 23/498; H01L 23/00; H05K 1/18

(52) U.S. Cl. CPC H01L 23/13; H01L 23/49822; H01L 24/20; H01L 25/16; H05K 1/181; H01L 24/16; H01L 24/19; H01L 24/32; H01L 24/73; H01L 2224/19; H01L 2224/2105; H01L 2224/05571; H01L 2224/05647; H01L 2224/16238; H01L 2224/32238; H01L 2224/73204; H01L 2924/1517; H01L 2924/19041; H01L 2924/19106; H05K 2201/2072; H05K 2201/09036; H05K 2201/10015; H05K 2201/10234; H05K 2201/10636; H05K 2201/10977

(57) ABSTRACT

A semiconductor package includes a redistribution substrate having a first surface and a second surface which are opposite to each other, a semiconductor chip mounted on the first surface of the redistribution substrate, an under bump interconnection layer on the second surface of the redistribution substrate, an electronic device mounted on the under bump interconnection layer, and a solder bump disposed on the under bump interconnection layer and horizontally spaced apart from the electronic device. The under bump interconnection layer includes conductive patterns respectively connected to the electronic device and the solder bump, and a passivation layer covering the conductive patterns. The passivation layer includes a plurality of trenches disposed between the electronic device and the solder bump.

### CROSS-REFERENCE TO RELATED APPLICATIONS

This U.S. Non-Provisional Pat. Application claims priority under 35 U.S.C. §119 to Korean Patent Application No. 10-2021-0128893, filed on Sep. 29, 2021, in the Korean Intellectual Property Office, the entire contents of which are hereby incorporated by reference.

### BACKGROUND OF THE INVENTION

The present disclosure relates to semiconductor packages and methods of manufacturing the same, and more particularly, to semiconductor packages in which semiconductor chips and electronic devices are mounted, and methods of manufacturing the same.

An integrated circuit chip may be realized in the form of a semiconductor package so as to be appropriately applied to an electronic product. In a typical semiconductor package, a semiconductor chip may be mounted on a printed circuit board (PCB) and may be electrically connected to the PCB through bonding wires or bumps. Small, light and multi-functional electronic products have been demanded with the development of the electronics industry, and thus various techniques have been studied to improve reliability and integration density of a semiconductor package and to reduce a size of a semiconductor package.

### SUMMARY

Embodiments of the inventive concepts may provide semiconductor packages with excellent reliability and methods of manufacturing the same.

Embodiments of the inventive concepts may also provide semiconductor packages capable of easily reducing their sizes and of easily improving their integration densities and methods of manufacturing the same.

In an aspect, a semiconductor package may include a redistribution substrate having a first surface and a second surface which are opposite to each other, a semiconductor chip mounted on the first surface of the redistribution substrate, an under bump interconnection layer on the second surface of the redistribution substrate, an electronic device mounted on the under bump interconnection layer, and a solder bump disposed on the under bump interconnection layer and horizontally spaced apart from the electronic device. The under bump interconnection layer may include conductive patterns respectively connected to the electronic device and the solder bump, and a passivation layer covering the conductive patterns. The passivation layer may include a plurality of trenches disposed between the electronic device and the solder bump.

In an aspect, a semiconductor package may include an under bump interconnection layer, an electronic device mounted on the under bump interconnection layer, and a plurality of solder bumps arranged to surround the electronic device on the under bump interconnection layer. The under bump interconnection layer may include conductive patterns respectively connected to the electronic device and the plurality of solder bumps, and a passivation layer covering the conductive patterns. The electronic device may have a first side surface and a second side surface, which are opposite to each other in a first direction parallel to a top surface of the passivation layer. The passivation layer may include a first group of trenches disposed between the first side surface of the electronic device and corresponding solder bumps of the plurality of solder bumps, and a second group of trenches disposed between the second side surface of the electronic device and corresponding solder bumps of the plurality of solder bumps. Each trench of the first group of trenches and the second group of trenches may have a line shape extending in a second direction which is parallel to the top surface of the passivation layer and intersects the first direction.

In an aspect, a semiconductor package may include an under bump interconnection layer, an electronic device mounted on the under bump interconnection layer, and a solder bump disposed on the under bump interconnection layer and horizontally spaced apart from the electronic device. The under bump interconnection layer may include conductive patterns connected to the electronic device and the solder bump, and a passivation layer covering the conductive patterns. The passivation layer may include a plurality of trenches disposed between the electronic device and the solder bump. The electronic device may be spaced apart from the solder bump by a first distance. The plurality of trenches may be located within a second distance from the solder bump, and the second distance may be half of the first distance.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a semiconductor package according to some embodiments of the inventive concepts.

FIG. 2 is a cross-sectional view taken along a line I-I' of FIG. 1, according to some embodiments.

FIG. 3 is an enlarged view illustrating a portion ‘A’ of FIG. 2.

FIGS. 4 and 5 are plan views illustrating semiconductor packages according to some embodiments of the inventive concepts.

FIG. 6 is a cross-sectional view illustrating a semiconductor package according to some embodiments of the inventive concepts.

FIGS. 7 and 8 are cross-sectional views illustrating a method of manufacturing a semiconductor package according to some embodiments of the inventive concepts.

FIG. 9 is a cross-sectional view illustrating a semiconductor package according to some embodiments of the inventive concepts.

FIGS. 10 and 11 are cross-sectional views illustrating a method of manufacturing a semiconductor package according to some embodiments of the inventive concepts.

FIG. 12 is a cross-sectional view illustrating a semiconductor package according to some embodiments of the inventive concepts.

FIGS. 13 and 14 are cross-sectional views illustrating a method of manufacturing a semiconductor package according to some embodiments of the inventive concepts.

FIG. 15 is a cross-sectional view illustrating a semiconductor package according to some embodiments of the inventive concepts.

FIG. 16 is a cross-sectional view illustrating a method of manufacturing a semiconductor package according to some embodiments of the inventive concepts.

### DETAILED DESCRIPTION

Example embodiments of the inventive concepts will now be described more fully with reference to the accompanying drawings.

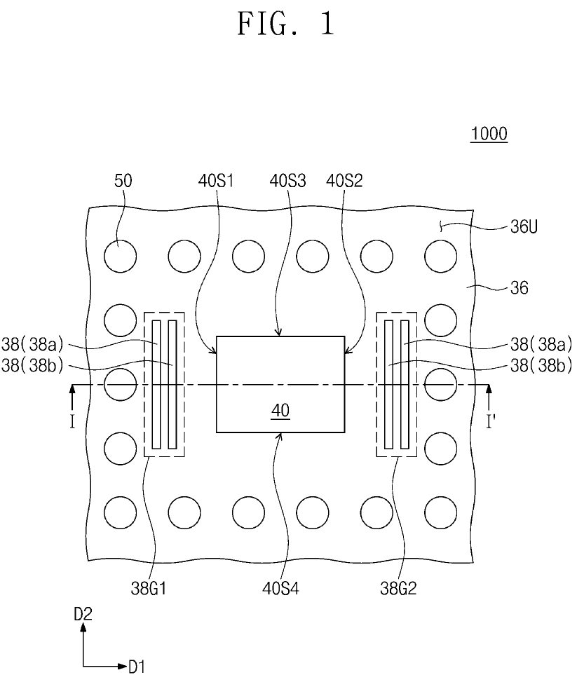

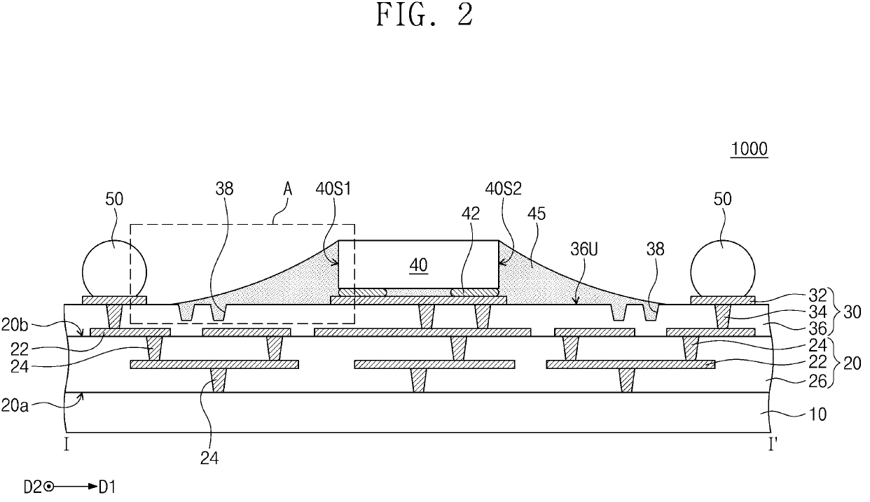

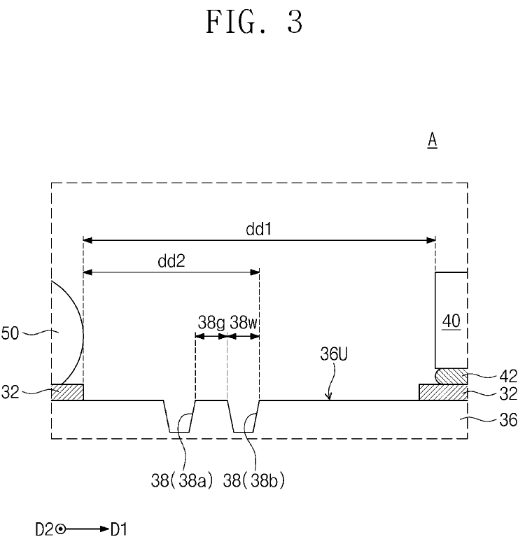

FIG. 1 is a plan view illustrating a semiconductor package according to some embodiments of the inventive concepts. FIG. 2 is a cross-sectional view taken along a line I-I' of FIG. 1, and FIG. 3 is an enlarged view illustrating a portion ‘A’ of FIG. 2. A component of FIG. 2 is omitted in FIG. 3 for the purpose of ease and convenience in illustration.

Referring to FIGS. 1 and 2, a semiconductor package 1000 may include a lower structure 10, a redistribution substrate 20 on the lower structure 10, an under bump interconnection layer 30 on the redistribution substrate 20, an electronic device 40 and a solder bump 50 (e.g., plurality of solder bumps) on the under bump interconnection layer 30, and an underfill layer 45 between the under bump interconnection layer 30 and the electronic device 40. The lower structure 10 may include or may be a printed circuit board, a semiconductor chip, or a semiconductor package.

The redistribution substrate 20 may have a first surface 20a and a second surface 20b, which are opposite to each other. The lower structure 10 may be disposed on the first surface 20a of the redistribution substrate 20, and the under bump interconnection layer 30 may be disposed on the second surface 20b of the redistribution substrate 20. The redistribution substrate 20 may include redistribution patterns 22 and 24 and a redistribution insulating layer 26 covering the redistribution patterns 22 and 24. The redistribution patterns 22 and 24 may include redistribution lines 22 spaced apart from each other in a direction perpendicular to the first surface 20a of the redistribution substrate 20, and redistribution contacts 24 connected to the redistribution lines 22. The redistribution lines 22 may be electrically connected to each other through the redistribution contacts 24. The redistribution lines 22 may extend lengthwise in a horizontal direction, parallel to the first surface 20a of the redistribution substrate 20, and the redistribution contacts 24 may extend lengthwise in a vertical direction through the redistribution layer 26. An item, layer, or portion of an item or layer described as extending “lengthwise” in a particular direction has a length in the particular direction and a width perpendicular to that direction, where the length is greater than the width. The redistribution patterns 22 and 24 may include or may be formed of a metal material (e.g., copper, titanium, and/or an alloy thereof), and the redistribution insulating layer 26 may include or may be formed of a photosensitive polymer. The redistribution insulating layer 26 may be formed of a plurality of stacked layers, each having the same material. The lower structure 10 may be electrically connected to corresponding redistribution patterns (e.g., corresponding redistribution contacts 24) of the redistribution patterns 22 and 24. The lower structure 10 may be electrically connected to the redistribution substrate 20 through the corresponding redistribution patterns (e.g., the corresponding redistribution contacts 24). Being “electrically connected” refers to two electrically conductive components being connected together so that an electrical voltage or current can pass from one to the other.

The under bump interconnection layer 30 may include conductive patterns 32 and 34, and a passivation layer 36 covering the conductive patterns 32 and 34. The under bump interconnection layer 30 may be a layer immediately adjacent to bumps (e.g., solder bumps) connected thereto. The conductive patterns 32 and 34 may include conductive pads 32, and conductive contacts 34 connected to the conductive pads 32. The passivation layer 36 may expose at least a portion of each of the conductive pads 32. The conductive contacts 34 may be disposed under the conductive pads 32 and in the passivation layer 36 and may be connected to the conductive pads 32. The conductive contacts 34 may be electrically connected to corresponding redistribution patterns (e.g., corresponding redistribution lines 22) of the redistribution patterns 22 and 24. The conductive pads 32 may be electrically connected to the redistribution substrate 20 through the conductive contacts 34 and the corresponding redistribution patterns (e.g., the corresponding redistribution lines 22). The conductive patterns 32 and 34 may include or may be formed of a metal material (e.g., copper, titanium and/or an alloy thereof). The passivation layer 36 may include or may be formed of an insulating material (e.g., an Ajinomoto build-up film (ABF), a photosensitive polymer, and/or a solder resist material). The combination of the redistribution substrate 20 and the under bump interconnection layer 30 may be referred to herein as a “package routing layer” or a “package routing structure.” As discussed herein, “pads” may be connected to internal circuitry within the device to which they are connected, and may transmit signals and/or supply voltages to and/or from the device to which they are attached. For example, pads disposed on a package routing layer may connect to rerouting and other electrical lines disposed within the package routing layer, and the pads disposed on the semiconductor chips may connect to an integrated circuit of one or more of the semiconductor chips. The various pads described herein may generally have a planar surface at a location for connecting to a terminal for external communications outside of the device to which the pads are connected. The pads may be formed of a conductive material, such a metal, for example. The pads may have a circular or equilateral polygonal shape, and unless noted otherwise, do not extend horizontally in a particular direction more than in a perpendicular horizontal direction that is perpendicular to the particular direction.

The electronic device 40 may be mounted on the under bump interconnection layer 30. The electronic device 40 may be disposed on a corresponding conductive pad 32 of the conductive pads 32, and a connection bump 42 may be disposed between the electronic device 40 and the corresponding conductive pad 32. The electronic device 40 may be electrically connected to the corresponding conductive pad 32 through the connection bump 42. For example, the electronic device 40 may be a passive device such as a capacitor. The connection bump 42 may include a conductive material and may have at least one shape of a solder ball, a bump, or a pillar. The electronic device 40 may be electrically connected to corresponding redistribution patterns 22 and 24 of the redistribution patterns 22 and 24 through corresponding conductive patterns 32 and 34 of the conductive patterns 32 and 34 and may be electrically connected to the lower structure 10 through the corresponding redistribution patterns 22 and 24.

The solder bump 50 may be disposed on the under bump interconnection layer 30 and may be horizontally spaced apart from the electronic device 40. The solder bump 50 may be disposed on a corresponding conductive pad 32 of the conductive pads 32 and may be connected to the corresponding conductive pad 32. The solder bump 50 may include or be formed of a conductive material and may have at least one shape of a solder ball, a bump, or a pillar. Each solder bump 50 may be electrically connected to corresponding redistribution patterns 22 and 24 of the redistribution patterns 22 and 24 through corresponding conductive patterns 32 and 34 of the conductive patterns 32 and 34 and may be electrically connected to the lower structure 10 through the corresponding redistribution patterns 22 and 24.

Referring to FIGS. 1 to 3, the passivation layer 36 of the under bump interconnection layer 30 may include a plurality of trenches 38 disposed horizontally between the electronic device 40 and the solder bump 50. Each of the plurality of trenches 38 may extend from a top surface 36U of the passivation layer 36, also described as a first surface of the passivation layer, into the passivation layer 36. Spatially relative terms, such as “beneath,” “below,” “lower,” “above,” “upper,” “top,” “bottom,” and the like, may be used herein for ease of description to describe positional relationships, such as illustrated in the figures, for example. It will be understood that the spatially relative terms encompass different orientations of the device in addition to the orientation depicted in the figures. Also, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). The plurality of trenches 38 may include a first trench 38a closest to the solder bump 50 and a second trench 38b farthest from the solder bump 50, such that the first trench 38a is horizontally between the solder bump 50 and the second trench 38b. The second trench 38b may be closer to the solder bump 50 than it is the electronic device 40, and the first trench 38a may be disposed between the solder bump 50 and the second trench 38b. Even though not shown in the drawings, additional trenches may be disposed between the first trench 38a and the second trench 38b. The electronic device 40 may be spaced apart from the solder bump 50 by a first distance dd1, and the plurality of trenches 38 may be located within a second distance dd2 from the solder bump 50. The second distance dd2 may be half of the first distance dd1 (i.e., dd2=0.5×dd1). Accordingly, a center of the second trench 38b, in the horizontal direction D1, may be closer to the solder bump 50 than it is to the electronic device 40.

The plurality of trenches 38 may be spaced apart from each other in a first direction D1 parallel to the top surface 36U of the passivation layer 36 and may extend in a second direction D2 which is parallel to the top surface 36U of the passivation layer 36 and intersects the first direction D1. In some embodiments, each of the plurality of trenches 38 may have a line shape extending in the second direction D2.

Each of the plurality of trenches 38 may have a width 38w in the first direction D1. The width 38w of each of the plurality of trenches 38 may become progressively greater from its bottom toward its top. For example, the width 38w of each of the plurality of trenches 38 may increase as a distance from the top surface 36U of the passivation layer 36 decreases. As an example, the maximum width 38w of each of the plurality of trenches 38 (e.g., at a top of the trench 38 and coplanar with the top surface 36U) may have a value in a range from 25 µm to 100 µm. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. The plurality of trenches 38 may include a pair of the trenches 38 directly adjacent to each other in the first direction D1, and for example, a distance 38g between the pair of trenches 38 may be in a range from 25 µm to 100 µm.

Referring again to FIGS. 1 and 2, the solder bump 50 may be provided in plurality. The plurality of solder bumps 50 may be disposed to surround the electronic device 40, when viewed in a plan view. The electronic device 40 may have a first side surface 40S1 and a second side surface 40S2 which are opposite to each other in the first direction D1 and may have a third side surface 40S3 and a fourth side surface 40S4 which are opposite to each other in the second direction D2. The plurality of solder bumps 50 may be disposed to surround the first to fourth side surfaces 40S1, 40S2, 40S3 and 40S4 of the electronic device 40. The plurality of trenches 38 may be disposed between the electronic device 40 and the plurality of solder bumps 50.

The plurality of trenches 38 may include a first group of trenches 38G1 disposed between the first side surface 40S1 of the electronic device 40 and corresponding solder bumps 50 of the solder bumps 50. The first group of trenches 38G1 may include a first plurality of trenches spaced apart from each other in the first direction D1, each trench extending in the second direction D2, and may be located between the first side surface 40S1 of the electronic device 40 and the corresponding solder bumps 50. Each trench of the first group of trenches 38G1 may have a line shape extending in the second direction D2. As illustrated in FIG. 3, the first group of trenches 38G1 may be located within the second distance dd2 from the corresponding solder bumps 50. As described with reference to FIG. 3, each trench of the first group of trenches 38G1 may have the maximum width 38w, and the first group of trenches 38G1 may be spaced apart from each other by the distance 38g.

The plurality of trenches 38 may further include a second group of trenches 38G2 disposed between the second side surface 40S2 of the electronic device 40 and corresponding solder bumps 50 of the solder bumps 50. The second group of trenches 38G2 may include a second plurality of trenches spaced apart from each other in the first direction D1, each trench extending in the second direction D2, and may be located between the second side surface 40S2 of the electronic device 40 and the corresponding solder bumps 50. Each trench of the second group of trenches 38G2 may have a line shape extending in the second direction D2. As described with reference to FIG. 3, the second group of trenches 38G2 may be located within the second distance dd2 from the corresponding solder bumps 50. As described with reference to FIG. 3, each trench of the second group of trenches 38G2 may have the maximum width 38w, and the second group of trenches 38G2 may be spaced apart from each other by the distance 38g.

The underfill layer 45 may fill a space between the under bump interconnection layer 30 and the electronic device 40. The underfill layer 45 may fill a space between the electronic device 40 and the corresponding conductive pad 32 and between the connection bumps 42. The underfill layer 45 may cover at least a portion of the side surfaces 40S1, 40S2, 40S3 and 40S4 of the electronic device 40 and may extend onto the top surface 36U of the passivation layer 36. The underfill layer 45 may fill at least a portion of the plurality of trenches 38. For example, the underfill layer 45 may fill some or all of the plurality of trenches, and for each trench filled with the underfill layer 45, the underfill material may entirely fill the trench, or may partly fill the trench. The underfill layer 45 may contact the passivation layer 36 in the trenches 38. The underfill layer 45 may include or may be formed of an insulating polymer material such as an epoxy resin.

Typically, when an underfill layer extends onto the top surface of a passivation layer, the underfill layer may come in contact with side surfaces of at least some of the solder bumps to contaminate the solder bumps. “Contact,” as used herein refers to a direct connection, i.e., touching.

According to aspects of the inventive concepts, the plurality of trenches 38 may be disposed between the electronic device 40 and the solder bump 50 and may inhibit the flow of the underfill layer 45. The plurality of trenches 38 may be located within the second distance dd2 from the solder bump 50, and the second distance dd2 may be half of the first distance dd1 (i.e., a distance between the electronic device 40 and the solder bump 50) (i.e., dd2=0.5×dd1). The width 38w of each of the plurality of trenches 38 may be in range from 25 µm to 100 µm, and the distance 38 g between the plurality of trenches 38 may range from 25 µm to 100 µm. The width 38w of different trenches 38 may be the same as other trenches 38, or in some cases may be different. However, in some embodiments, each trench 38 has a width 38w (e.g., maximum width in the D2 direction) that is between 25 µm and 100 µm. Since the plurality of trenches 38 is formed to satisfy the aforementioned conditions, the flow of the underfill layer 45 may be effectively inhibited in a limited area between the electronic device 40 and the solder bump 50.

In addition, a contact interface between the passivation layer 36 and the underfill layer 45 may be increased by the plurality of trenches 38, and thus a delamination phenomenon of the underfill layer 45 may be minimized.

As a result, reliability of the semiconductor package 1000 may be improved, and the semiconductor package 1000 may be easily miniaturized and highly integrated.

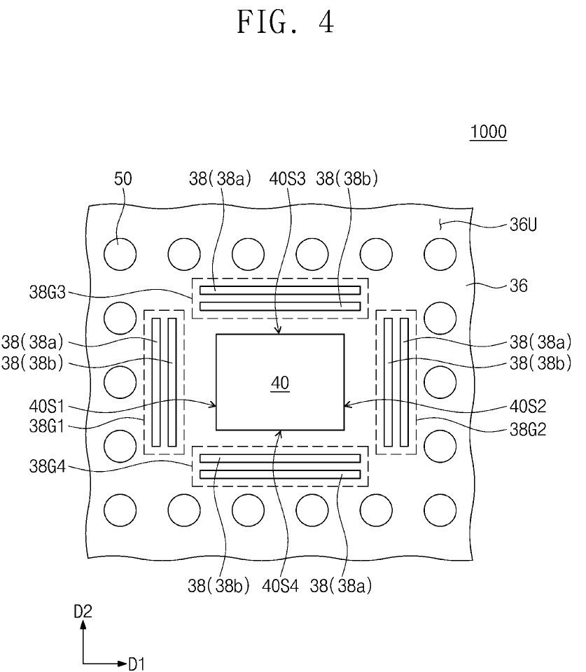

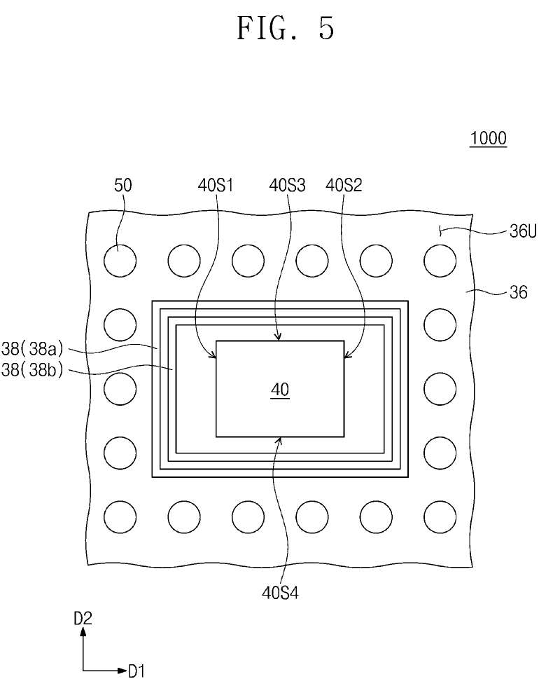

FIGS. 4 and 5 are plan views illustrating semiconductor packages according to some embodiments of the inventive concepts. Hereinafter, differences between the present embodiments and the above embodiments of FIGS. 1 to 3 will be mainly described for the purpose of ease and convenience in explanation.

Referring to FIG. 4, the plurality of trenches 38 may further include a third group of trenches 38G3 disposed between the third side surface 40S3 of the electronic device 40 and corresponding solder bumps 50 of the solder bumps 50, and a fourth group of trenches 38G4 disposed between the fourth side surface 40S4 of the electronic device 40 and corresponding solder bumps 50 of the solder bumps 50.

The third group of trenches 38G3 may extend in the first direction D1 and may be spaced apart from each other in the second direction D2, between the third side surface 40S3 of the electronic device 40 and the corresponding solder bumps 50. Each trench of the third group of trenches 38G3 may have a line shape extending in the first direction D1. As described with reference to FIG. 3, the third group of trenches 38G3 may be located within the second distance dd2 from the corresponding solder bumps 50. Each of the third group of trenches 38G3 may have a width in the second direction D2, and the width of each of the third group of trenches 38G3 may be substantially equal to the width 38w of each of the plurality of trenches 38, described with reference to FIG. 3. The third group of trenches 38G3 may include a pair of trenches 38 adjacent directly to each other in the second direction D2, and a distance between the pair of trenches 38 may be substantially equal to the distance 38g between the pair of trenches 38, described with reference to FIG. 3.

The fourth group of trenches 38G4 may extend in the first direction D1 and may be spaced apart from each other in the second direction D2, between the fourth side surface 40S4 of the electronic device 40 and the corresponding solder bumps 50. Each of the fourth group of trenches 38G4 may have a line shape extending in the first direction D1. As described with reference to FIG. 3, the fourth group of trenches 38G4 may be located within the second distance dd2 from the corresponding solder bumps 50. Each trench of the fourth group of trenches 38G4 may have a width in the second direction D2, and the width of each of the fourth group of trenches 38G4 may be substantially equal to the width 38w of each of the plurality of trenches 38, described with reference to FIG. 3. The fourth group of trenches 38G4 may include a pair of trenches 38 adjacent directly to each other in the second direction D2, and a distance between the pair of trenches 38 may be substantially equal to the distance 38g between the pair of trenches 38, described with reference to FIG. 3.

In some embodiments, the first group of trenches 38G1, the second group of trenches 38G2, the third group of trenches 38G3 and the fourth group of trenches 38G4 may be spaced apart from each other.

Referring to FIG. 5, the plurality of trenches 38 may be disposed between the electronic device 40 and the plurality of solder bumps 50. In some embodiments, each of the plurality of trenches 38 may have a ring shape surrounding the first to fourth side surfaces 40S1, 40S2, 40S3 and 40S4 of the electronic device 40. For example, each trench may extend continuously to surround the first to fourth side surfaces 40S1, 40S2, 40S3 and 40S4 of the electronic device 40.

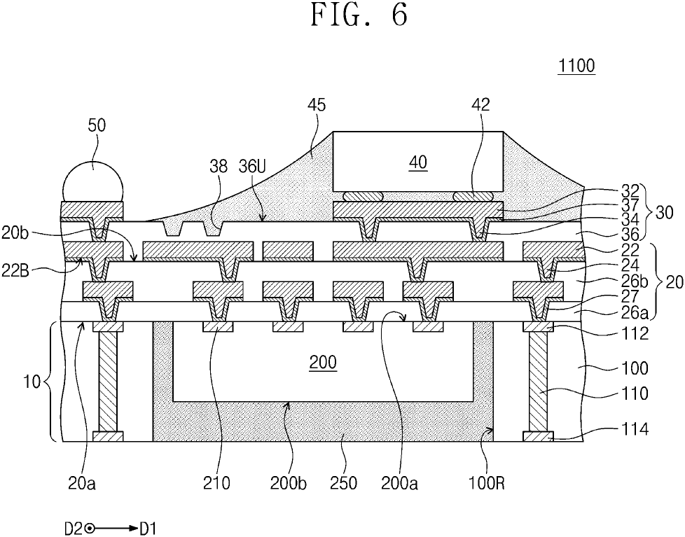

FIG. 6 is a cross-sectional view illustrating a semiconductor package according to some embodiments of the inventive concepts. Hereinafter, differences between the present embodiments and the above embodiments of FIGS. 1 to 5 will be mainly described for the purpose of ease and convenience in explanation.

Referring to FIG. 6, a semiconductor package 1100 may include a lower structure 10, a redistribution substrate 20 on the lower structure 10, an under bump interconnection layer 30 on the redistribution substrate 20, an electronic device 40 and a solder bump 50 on the under bump interconnection layer 30, and an underfill layer 45 between the under bump interconnection layer 30 and the electronic device 40.

The redistribution substrate 20 may have a first surface 20a and a second surface 20b, which are opposite to each other. The lower structure 10 may be disposed on the first surface 20a of the redistribution substrate 20, and the under bump interconnection layer 30 may be disposed on the second surface 20b of the redistribution substrate 20.

The redistribution substrate 20 may include redistribution patterns 22, 24 and 27 and redistribution insulating layers 26a and 26b covering the redistribution patterns 22, 24 and 27. The redistribution patterns 22, 24 and 27 may include redistribution lines 22 spaced apart from each other in a direction perpendicular to the first surface 20a of the redistribution substrate 20, redistribution contacts 24 connected to the redistribution lines 22, and redistribution seed patterns 27. Each of the redistribution contacts 24 may extend from a bottom surface 22B of a corresponding redistribution line 22 of the redistribution lines 22 toward the first surface 20a of the redistribution substrate 20. Each of the redistribution contacts 24 may be in contact with the corresponding redistribution line 22 without an interface therebetween. For example, a redistribution contact 24 and corresponding redistribution line 22 may be integrally formed of the same material to form a unitary body with no grain boundaries therebetween. Each of the redistribution contacts 24 may have a width in a direction (e.g., the first direction D1) parallel to the first surface 20a of the redistribution substrate 20, and the width of each of the redistribution contacts 24 may become progressively greater toward the bottom surface 22B of the corresponding redistribution line 22. Each of the redistribution seed patterns 27 may cover a bottom surface 22B of a corresponding redistribution line 22 of the redistribution lines 22 and may extend along a side surface and a bottom surface of a corresponding redistribution contact 24 of the redistribution contacts 24. The redistribution lines 22 and the redistribution contacts 24 may include or be formed of a metal material (e.g., copper), and the redistribution seed patterns 27 may include or be formed of a conductive seed material (e.g., copper, titanium, and/or an alloy thereof).

The redistribution insulating layers 26a and 26b may include a first redistribution insulating layer 26a adjacent to the first surface 20a of the redistribution substrate 20, and a second redistribution insulating layer 26b adjacent to the second surface 20b of the redistribution substrate 20. The first redistribution insulating layer 26a and the second redistribution insulating layer 26b may cover the redistribution patterns 22, 24 and 27, and some of the redistribution lines 22 may be disposed on the second redistribution insulating layer 26b. The some of the redistribution lines 22 may be disposed on the second surface 20b of the redistribution substrate 20. The first redistribution insulating layer 26a and the second redistribution insulating layer 26b may include or be formed of the same material and may include or be, for example, a photosensitive polymer.

The under bump interconnection layer 30 may include conductive patterns 32, 34 and 37, and a passivation layer 36 covering the conductive patterns 32, 34 and 37. The conductive patterns 32, 34 and 37 may include conductive pads 32 (also described as conductive line patterns), conductive contacts 34 connected to the conductive pads 32, and conductive seed patterns 37. The conductive pads 32 may be disposed on a top surface 36U of the passivation layer 36 and may be horizontally spaced apart from each other (e.g., in the first direction D1). Each of the conductive contacts 34 may extend from a bottom surface of a corresponding conductive pad 32 of the conductive pads 32 into the passivation layer 36. Each of the conductive contacts 34 may be in contact with the corresponding conductive pad 32 without an interface therebetween. For example, a conductive contact 35 and corresponding conductive pad 32 may be integrally formed of the same material to form a unitary body with no grain boundaries therebetween. Each of the conductive contacts 34 may have a width in the first direction D1, and the width of each of the conductive contacts 34 may become progressively greater in a direction toward the bottom surface of the corresponding conductive pad 32. Each of the conductive seed patterns 37 may cover a bottom surface of a corresponding conductive pad 32 of the conductive pads 32 and may extend along a side surface and a bottom surface of a corresponding conductive contact 34 of the conductive contacts 34. The conductive pads 32 and the conductive contacts 34 may include or be formed of a metal material (e.g., copper), and the conductive seed patterns 37 may include or be formed of a conductive seed material (e.g., copper, titanium, and/or an alloy thereof).

The passivation layer 36 may be disposed on the second surface 20b of the redistribution substrate 20 and may cover corresponding redistribution patterns (e.g., the some of the redistribution lines 22) of the redistribution patterns 22 and 24. The passivation layer 36 may expose at least a portion of each of the conductive pads 32. For example, the conductive pads 32 may be disposed on the passivation layer 36. The conductive contacts 34 may be disposed in the passivation layer 36 and may be connected to the conductive pads 32. The conductive contacts 34 may be electrically connected to corresponding redistribution patterns (e.g., the some of the redistribution lines 22) of the redistribution patterns 22 and 24. The passivation layer 36 may include or be formed of an insulating material (e.g., an Ajinomoto build-up film (ABF)).

The electronic device 40 may be mounted on the under bump interconnection layer 30. The electronic device 40 may be disposed on a corresponding conductive pad 32 of the conductive pads 32, and a connection bump 42 may be disposed between the electronic device 40 and the corresponding conductive pad 32. The electronic device 40 may be electrically connected to the corresponding conductive pad 32 through the connection bump 42. For example, the electronic device 40 may be a passive device such as a capacitor. The solder bump 50 may be disposed on the under bump interconnection layer 30 and may be horizontally spaced apart from the electronic device 40, for example at least partly at the same vertical height above the bass substrate 100. The solder bump 50 may be disposed on a corresponding conductive pad 32 of the conductive pads 32 and may be connected to the corresponding conductive pad 32.

The passivation layer 36 may include a plurality of trenches 38 disposed between the electronic device 40 and the solder bump 50. The plurality of trenches 38 may be substantially the same as the plurality of trenches 38 described with reference to FIGS. 1 to 5. The underfill layer 45 may fill a space between the under bump interconnection layer 30 and the electronic device 40. The underfill layer 45 may fill a space between the electronic device 40 and the corresponding conductive pad 32 and between the connection bumps 42. The underfill layer 45 may extend onto the top surface 36U of the passivation layer 36 and may fill at least a portion of the plurality of trenches 38. The underfill layer 45 may contact the passivation layer 36 in the trenches 38.

In some embodiments, the lower structure 10 may include a base substrate 100 disposed on the first surface 20a of the redistribution substrate 20. The base substrate 100 may include or be formed of an insulating material and may include or be, for example, a carbon-based material, a ceramic, or a polymer. The base substrate 100 may include a substrate hole 100R penetrating the base substrate 100. The substrate hole 100R may expose an inner side surface of the base substrate 100.

The lower structure 10 may further include a semiconductor chip 200 disposed in the substrate hole 100R. The semiconductor chip 200 may be disposed to be spaced apart from the inner side surface of the base substrate 100. The semiconductor chip 200 may be a memory chip, a logic chip, an application processor (AP) chip, or a system-on-chip (SOC). The semiconductor chip 200 may have a first surface 200a and a second surface 200b, which are opposite to each other, and may include chip pads 210 disposed adjacent to or at the first surface 200a. The semiconductor chip 200 may be disposed in such a way that the first surface 200a of the semiconductor chip 200 faces the first surface 20a of the redistribution substrate 20. Each of the chip pads 210 may be connected to a corresponding redistribution contact 24 of the redistribution contacts 24. A corresponding redistribution seed pattern 27 of the redistribution seed patterns 27 may be disposed between each of the chip pads 210 and the corresponding redistribution contact 24. The chip pads 210 may include or be a metal (e.g., copper). The semiconductor chip 200 may be electrically connected to the redistribution substrate 20 through the chip pads 210.

The lower structure 10 may further include a conductive structure 110 disposed in the base substrate 100, a first pad 112 connected to one end of the conductive structure 110, and a second pad 114 connected to another end of the conductive structure 110. The conductive structure 110 may be a metal pillar penetrating the base substrate 100. The first pad 112 and the second pad 114 may be electrically connected to each other through the conductive structure 110. The first pad 112 may be connected to a corresponding redistribution contact 24 of the redistribution contacts 24. A corresponding redistribution seed pattern 27 of the redistribution seed patterns 27 may be disposed between the first pad 112 and the corresponding redistribution contact 24. For example, each of the conductive structure 110, the first pad 112 and the second pad 114 may include or be formed of at least one of copper, aluminum, tungsten, titanium, tantalum, iron, or an alloy thereof. The conductive structure 110 may be electrically connected to the redistribution substrate 20 through the first pad 112.

The lower structure 10 may further include a molding layer 250 which is disposed in the substrate hole 100R and covers the semiconductor chip 200. The molding layer 250 may cover the second surface 200b of the semiconductor chip 200 and may extend between the semiconductor chip 200 and the inner side surface of the base substrate 100. The molding layer 250 may include or be an adhesive insulating film (e.g., an Ajinomoto build-up film (ABF)), or an insulating polymer (e.g., an epoxy-based polymer).

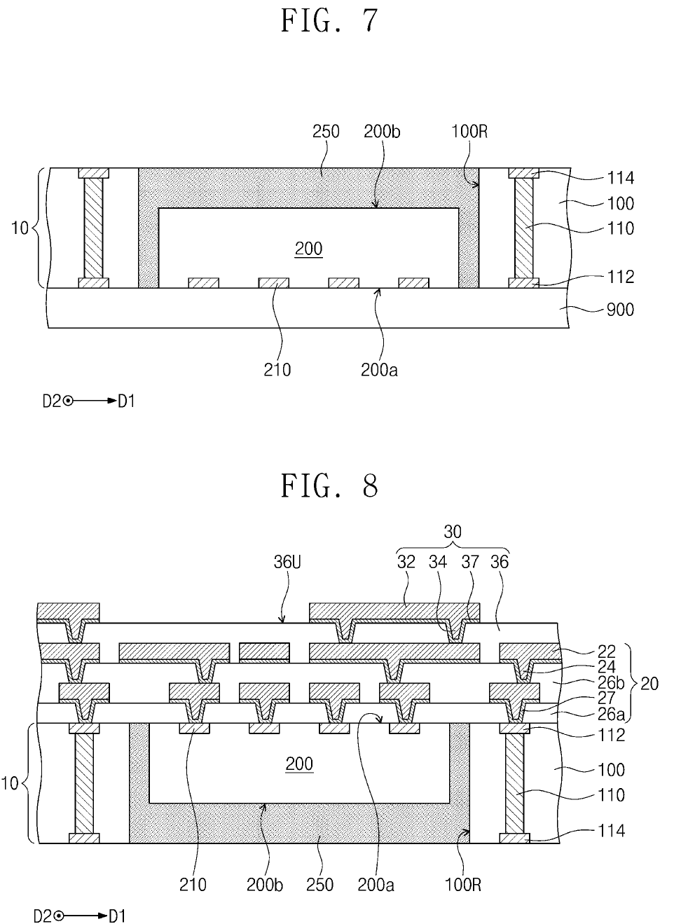

FIGS. 7 and 8 are cross-sectional views illustrating a method of manufacturing a semiconductor package according to some embodiments of the inventive concepts. Hereinafter, the descriptions to the same features as described with reference to FIG. 6 will be omitted for the purpose of ease and convenience in explanation.

Referring to FIG. 7, a base substrate 100 may be provided on a carrier substrate 900. The base substrate 100 may include a substrate hole 100R penetrating the base substrate 100. A conductive structure 110 may be formed in the base substrate 100 and may penetrate the base substrate 100. The conductive structure 110 may be horizontally spaced apart from the substrate hole 100R. A first pad 112 may be connected to one end of the conductive structure 110, and a second pad 114 may be connected to another end of the conductive structure 110.

A semiconductor chip 200 may be provided in the substrate hole 100R of the base substrate 100. The semiconductor chip 200 may have a first surface 200a and a second surface 200b, which are opposite to each other, and may include chip pads 210 disposed at or adjacent to the first surface 200a. The semiconductor chip 200 may be disposed in such a way that the first surface 200a of the semiconductor chip 200 faces a top surface of the carrier substrate 900. A molding layer 250 may be provided in the substrate hole 100R and may cover the second surface 200b of the semiconductor chip 200. The molding layer 250 may extend between the semiconductor chip 200 and the base substrate 100.

The base substrate 100, the conductive structure 110, the first and second pads 112 and 114, the semiconductor chip 200 and the molding layer 250 may constitute a lower structure 10.

Referring to FIG. 8, the carrier substrate 900 may be removed. A redistribution substrate 20 and an under bump interconnection layer 30 may be sequentially formed on one surface of the lower structure 10, which is exposed by the removal of the carrier substrate 900.

For example, the formation of the redistribution substrate 20 may include forming a first redistribution insulating layer 26a on the one surface of the lower structure 10, forming redistribution contact holes penetrating the first redistribution insulating layer 26a, forming a redistribution seed pattern 27 which fills a portion of each of the redistribution contact holes and extends onto a top surface of the first redistribution insulating layer 26a, and performing an electroplating process using the redistribution seed pattern 27 to form a redistribution contact 24 and a redistribution line 22. The first redistribution insulating layer 26a may cover the first surface 200a of the semiconductor chip 200, one surface of the base substrate 100, and the molding layer 250 between the semiconductor chip 200 and the base substrate 100. The redistribution contact 24 may fill a remaining portion of each of the redistribution contact holes, and the redistribution line 22 may extend onto the first redistribution insulating layer 26a.

For example, the formation of the redistribution substrate 20 may further include forming a second redistribution insulating layer 26b on the first redistribution insulating layer 26a, and forming additional redistribution seed patterns 27, additional redistribution contacts 24 and additional redistribution lines 22 on the second redistribution insulating layer 26b. The additional redistribution seed patterns 27, the additional redistribution contacts 24 and the additional redistribution lines 22 may be formed by substantially the same method as the redistribution seed pattern 27, the redistribution contact 24 and the redistribution line 22.

For example, the formation of the under bump interconnection layer 30 may include forming a passivation layer 36 on the second redistribution insulating layer 26b, forming conductive contact holes penetrating the passivation layer 36, forming a conductive seed pattern 37 which fills a portion of each of the conductive contact holes and extends onto a top surface 36U of the passivation layer 36, and performing an electroplating process using the conductive seed pattern 37 to form a conductive contact 34 and a conductive pad 32.

Referring again to FIG. 6, a plurality of trenches 38 may be formed in the passivation layer 36. Each of the plurality of trenches 38 may extend from the top surface 36U of the passivation layer 36 into the passivation layer 36. The plurality of trenches 38 may be formed by etching an upper portion of the passivation layer 36. The etching of the upper portion of the passivation layer 36 may be performed using, for example, a dry etching process or a laser etching process. The plurality of trenches 38 may be formed at substantially the same positions as the plurality of trenches 38 described with reference to FIGS. 1 to 5 and may be formed to have substantially the same width 38w, distance 38g and shape as the plurality of trenches 38 described with reference to FIGS. 1 to 5.

An electronic device 40 may be mounted on the under bump interconnection layer 30. The electronic device 40 may be disposed on a corresponding conductive pad 32 of the conductive pads 32, and a connection bump 42 may be disposed between the electronic device 40 and the corresponding conductive pad 32. The electronic device 40 may be electrically connected to the corresponding conductive pad 32 through the connection bump 42. A solder bump 50 may be disposed on the under bump interconnection layer 30 and may be horizontally spaced apart from the electronic device 40. The solder bump 50 may be disposed on a corresponding conductive pad 32 of the conductive pads 32 and may be connected to the corresponding conductive pad 32. The plurality of trenches 38 may be formed to be disposed between the electronic device 40 and the solder bump 50.

An underfill layer 45 may be formed to fill a space between the electronic device 40 and the corresponding conductive pad 32 and between the connection bumps 42 and may extend onto the top surface 36U of the passivation layer 36. The underfill layer 45 may fill at least a portion of the plurality of trenches 38.

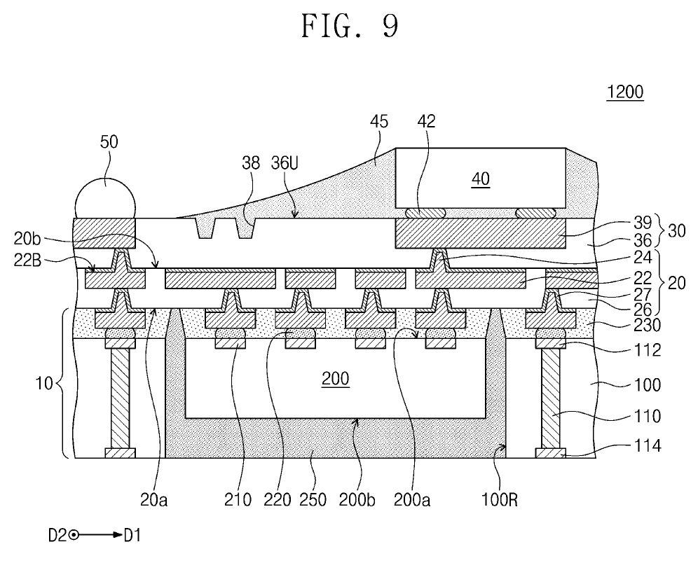

FIG. 9 is a cross-sectional view illustrating a semiconductor package according to some embodiments of the inventive concepts. Hereinafter, differences between the present embodiments and the above embodiments of FIG. 6 will be mainly described for the purpose of ease and convenience in explanation.

Referring to FIG. 9, a semiconductor package 1200 may include a lower structure 10, a redistribution substrate 20 on the lower structure 10, an under bump interconnection layer 30 on the redistribution substrate 20, an electronic device 40 and a solder bump 50 on the under bump interconnection layer 30, and an underfill layer 45 between the under bump interconnection layer 30 and the electronic device 40.

The redistribution substrate 20 may have a first surface 20a and a second surface 20b, which are opposite to each other. The lower structure 10 may be disposed on the first surface 20a of the redistribution substrate 20, and the under bump interconnection layer 30 may be disposed on the second surface 20b of the redistribution substrate 20.

The redistribution substrate 20 may include redistribution patterns 22, 24 and 27 and a redistribution insulating layer 26 covering the redistribution patterns 22, 24 and 27. The redistribution patterns 22, 24 and 27 may include redistribution lines 22 spaced apart from each other in a direction perpendicular to the first surface 20a of the redistribution substrate 20, redistribution contacts 24 connected to the redistribution lines 22, and redistribution seed patterns 27. Each of the redistribution contacts 24 may extend from a bottom surface 22B of a corresponding redistribution line 22 of the redistribution lines 22 toward the second surface 20b of the redistribution substrate 20. In the present embodiment, the redistribution lines 22 may be disposed in such a way that the bottom surfaces 22B of the redistribution lines 22 face the second surface 20b of the redistribution substrate 20.

Each of the redistribution seed patterns 27 may cover the bottom surface 22B of a corresponding redistribution line 22 of the redistribution lines 22 and may extend along a side surface and a bottom surface of a corresponding redistribution contact 24 of the redistribution contacts 24. Some of the redistribution lines 22 may be disposed on the first surface 20a of the redistribution substrate 20, and others of the redistribution contacts 24 may be disposed on the second surface 20b of the redistribution substrate 20. The redistribution insulating layer 26 may cover the redistribution patterns 22, 24 and 27 and may include, for example, a photosensitive polymer.

The under bump interconnection layer 30 may include under bump patterns 39, and a passivation layer 36 covering the under bump patterns 39. The under bump patterns 39 may be horizontally spaced apart from each other in the passivation layer 36 (e.g., in the first direction D1). Each of the under bump patterns 39 may be connected to a corresponding redistribution contact 24 of the redistribution contacts 24. A corresponding redistribution seed pattern 27 of the redistribution seed patterns 27 may be disposed between each of the under bump patterns 39 and the corresponding redistribution contact 24. The under bump patterns 39 may include or be formed of a metal material (e.g., copper). The under bump patterns 39 may be referred to as conductive patterns.

The passivation layer 36 may be disposed on the second surface 20b of the redistribution substrate 20 and may cover corresponding redistribution patterns (e.g., the corresponding redistribution contacts 24) of the redistribution patterns 22, 24 and 27. The passivation layer 36 may cover the under bump patterns 39 and may expose top surfaces of the under bump patterns 39. In some embodiments, the passivation layer 36 may include or be formed of the same material as the redistribution insulating layer 26. The passivation layer 36 may include, for example, a photosensitive polymer.

The electronic device 40 may be mounted on the under bump interconnection layer 30. The electronic device 40 may be disposed on a corresponding under bump pattern 39 of the under bump patterns 39, and a connection bump 42 may be disposed between the electronic device 40 and the corresponding under bump pattern 39. The electronic device 40 may be electrically connected to the corresponding under bump pattern 39 through the connection bump 42. The solder bump 50 may be disposed on the under bump interconnection layer 30 and may be horizontally spaced apart from the electronic device 40. The solder bump 50 may be disposed on a corresponding under bump pattern 39 of the under bump patterns 39 and may be connected to the corresponding under bump pattern 39.

The passivation layer 36 may include a plurality of trenches 38 disposed between the electronic device 40 and the solder bump 50. The plurality of trenches 38 may be substantially the same as the plurality of trenches 38 described with reference to FIGS. 1 to 5. The underfill layer 45 may fill a space between the under bump interconnection layer 30 and the electronic device 40. The underfill layer 45 may fill a space between the electronic device 40 and the corresponding under bump pattern 39 and between the connection bumps 42. The underfill layer 45 may extend onto the top surface 36U of the passivation layer 36 and may fill at least a portion of the plurality of trenches 38.

The lower structure 10 may include a base substrate 100 disposed on the first surface 20a of the redistribution substrate 20, a semiconductor chip 200 disposed in a substrate hole 100R of the base substrate 100, a conductive structure 110 disposed in the base substrate 100, a first pad 112 connected to one end of the conductive structure 110, a second pad 114 connected to another end of the conductive structure 110, and a molding layer 250 disposed in the substrate hole 100R and covering the semiconductor chip 200. The semiconductor chip 200 may have a first surface 200a and a second surface 200b, which are opposite to each other, and may include chip pads 210 disposed adjacent to the first surface 200a.

In some embodiments, the lower structure 10 may further include lower connection bumps 220 disposed on the chip pads 210 and the first pad 112, respectively. The chip pads 210 may be connected to corresponding redistribution lines 22 of the redistribution lines 22 through corresponding lower connection bumps 220 of the lower connection bumps 220, respectively. The semiconductor chip 200 may be electrically connected to the redistribution substrate 20 through the chip pads 210 and the corresponding lower connection bumps 220. The first pad 112 may be connected to a corresponding redistribution line 22 of the redistribution lines 22 through a corresponding lower connection bump 220 of the lower connection bumps 220. The conductive structure 110 may be electrically connected to the redistribution substrate 20 through the first pad 112 and the corresponding lower connection bump 220. The lower connection bump 220 may include or be formed of a conductive material and may have at least one shape of a solder ball, a bump, or a pillar.

According to some embodiments, the lower structure 10 may further include a lower underfill layer 230 disposed between the first surface 20a of the redistribution substrate 20 and the semiconductor chip 200 and between the first surface 20a of the redistribution substrate 20 and the base substrate 100. The lower underfill layer 230 may fill a space between the lower connection bumps 220 and a space between corresponding redistribution lines 22 of the redistribution lines 22, between the first surface 20a of the redistribution substrate 20 and the semiconductor chip 200. The lower underfill layer 230 may fill a space between the lower connection bumps 220 and a space between corresponding redistribution lines 22 of the redistribution lines 22, between the first surface 20a of the redistribution substrate 20 and the base substrate 100. The lower underfill layer 230 may include or be formed of an insulating polymer material such as an epoxy resin. The molding layer 250 may cover the second surface 200b of the semiconductor chip 200 and may extend between the semiconductor chip 200 and the inner side surface of the base substrate 100. In some embodiments, the molding layer 250 may extend between the lower underfill layers 230 adjacent to each other.

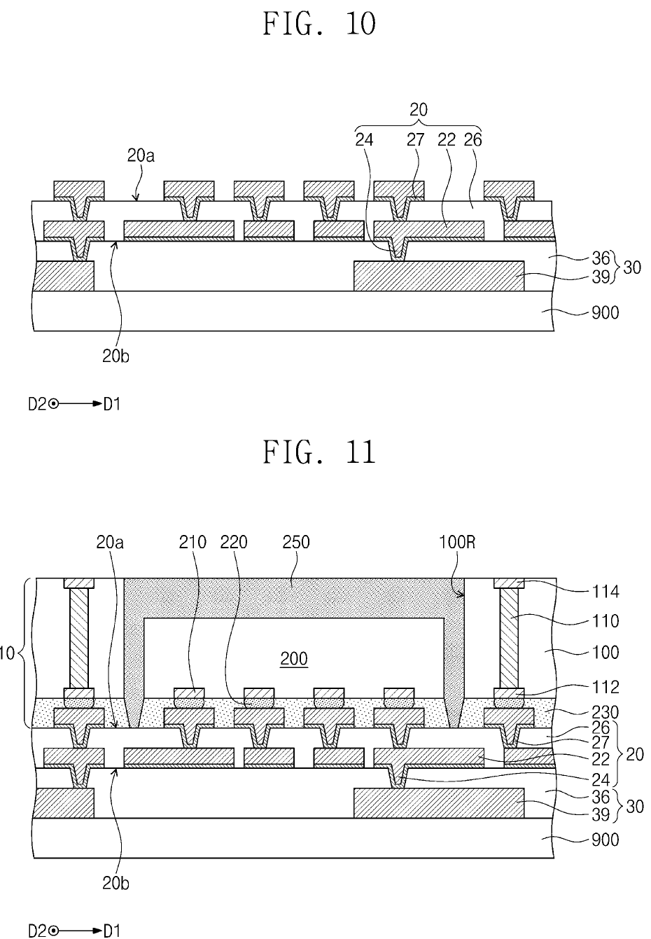

FIGS. 10 and 11 are cross-sectional views illustrating a method of manufacturing a semiconductor package according to some embodiments of the inventive concepts. Hereinafter, the descriptions to the same features as described with reference to FIG. 9 will be omitted for the purpose of ease and convenience in explanation.

Referring to FIG. 10, an under bump interconnection layer 30 and a redistribution substrate 20 may be sequentially formed on a carrier substrate 900.

For example, the formation of the under bump interconnection layer 30 may include forming under bump patterns 39 on the carrier substrate 900, and forming a passivation layer 36 covering the under bump patterns 39 on the carrier substrate 900. The under bump patterns 39 may be formed by, for example, an electroplating process.

For example, the formation of the redistribution substrate 20 may include forming redistribution contact holes penetrating an upper portion of the passivation layer 36, forming a redistribution seed pattern 27 which fills a portion of each of the redistribution contact holes and extends onto one surface of the passivation layer 36, and performing an electroplating process using the redistribution seed pattern 27 to form a redistribution contact 24 and a redistribution line 22. The redistribution contact holes may expose top surfaces of the under bump patterns 39, respectively. The redistribution contact 24 may fill a remaining portion of each of the redistribution contact holes, and the redistribution line 22 may extend onto the one surface of the passivation layer 36.

For example, the formation of the redistribution substrate 20 may further include forming a redistribution insulating layer 26 covering the redistribution contacts 24 and the redistribution lines 22 on the passivation layer 36, and forming additional redistribution seed patterns 27, additional redistribution contacts 24 and additional redistribution lines 22 on the redistribution insulating layer 26. The additional redistribution seed patterns 27, the additional redistribution contacts 24 and the additional redistribution lines 22 may be formed by substantially the same method as the redistribution seed pattern 27, the redistribution contact 24 and the redistribution line 22.

The redistribution substrate 20 may have a first surface 20a and a second surface 20b which are opposite to each other, and the second surface 20b of the redistribution substrate 20 may be adjacent to the under bump interconnection layer 30.

Referring to FIG. 11, a lower structure 10 may be provided on the first surface 20a of the redistribution substrate 20. The lower structure 10 may include a base substrate 100, a semiconductor chip 200 disposed in a substrate hole 100R of the base substrate 100, a conductive structure 110 disposed in the base substrate 100, a first pad 112 connected to one end of the conductive structure 110, a second pad 114 connected to another end of the conductive structure 110, a molding layer 250 disposed in the substrate hole 100R and covering the semiconductor chip 200, lower connection bumps 220 disposed between chip pads 210 of the semiconductor chip 200 and corresponding redistribution lines 22 and between the first pad 112 and a corresponding redistribution line 22, and a lower underfill layer 230 filling a space between the lower connection bumps 220.

Referring again to FIG. 9, the carrier substrate 900 may be removed. An electronic device 40 and a solder bump 50 may be provided on a surface of the under bump interconnection layer 30, which is exposed by the removal of the carrier substrate 900. The electronic device 40 may be disposed on a corresponding under bump pattern 39 of the under bump patterns 39, and a connection bump 42 may be disposed between the electronic device 40 and the corresponding under bump pattern 39. The electronic device 40 may be electrically connected to the corresponding under bump pattern 39 through the connection bump 42. The solder bump 50 may be horizontally spaced apart from the electronic device 40. The solder bump 50 may be disposed on a corresponding under bump pattern 39 of the under bump patterns 39 and may be connected to the corresponding under bump pattern 39.

A plurality of trenches 38 may be formed in the passivation layer 36 between the electronic device 40 and the solder bump 50. The plurality of trenches 38 may be formed by substantially the same method as the plurality of trenches 38 described with reference to FIGS. 6 to 8. An underfill layer 45 may be formed to fill a space between the electronic device 40 and the corresponding under bump pattern 39 and between the connection bumps 4 and may extend onto a top surface 36U of the passivation layer 36. The underfill layer 45 may fill at least a portion of the plurality of trenches 38.

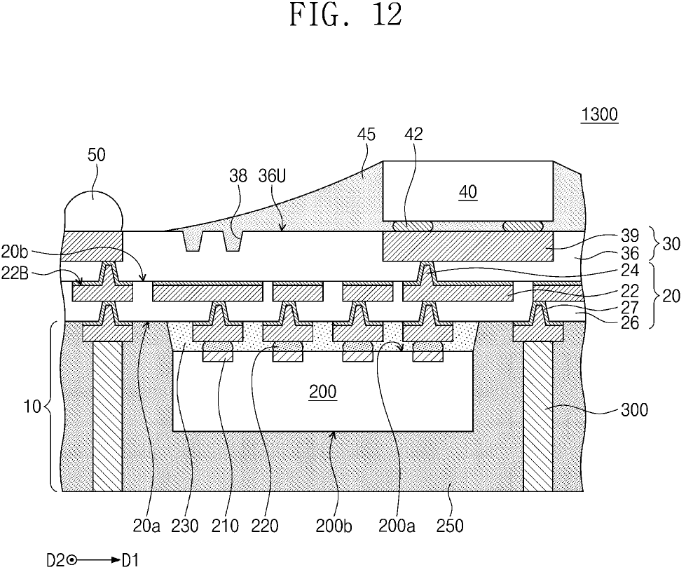

FIG. 12 is a cross-sectional view illustrating a semiconductor package according to some embodiments of the inventive concepts. Hereinafter, differences between the present embodiments and the above embodiments of FIG. 9 will be mainly described for the purpose of ease and convenience in explanation.

Referring to FIG. 12, a semiconductor package 1300 may include a lower structure 10, a redistribution substrate 20 on the lower structure 10, an under bump interconnection layer 30 on the redistribution substrate 20, an electronic device 40 and a solder bump 50 on the under bump interconnection layer 30, and an underfill layer 45 between the under bump interconnection layer 30 and the electronic device 40. The redistribution substrate 20, the under bump interconnection layer 30, the electronic device 40, the solder bump 50 and the underfill layer 45 may be substantially the same as the redistribution substrate 20, the under bump interconnection layer 30, the electronic device 40, the solder bump 50 and the underfill layer 45 of the semiconductor package 1200 described with reference to FIG. 9.

According to some embodiments, the lower structure 10 may include a semiconductor chip 200 and a conductive post 300 on the first surface 20a of the redistribution substrate 20. The semiconductor chip 200 may have a first surface 200a and a second surface 200b, which are opposite to each other, and may include chip pads 210 disposed at and adjacent to the first surface 200a. The lower structure 10 may further include lower connection bumps 220 disposed on the chip pads 210, respectively. The chip pads 210 may be connected to corresponding redistribution lines 22 of the redistribution lines 22 through corresponding lower connection bumps 220 of the lower connection bumps 220, respectively. The semiconductor chip 200 may be electrically connected to the redistribution substrate 20 through the chip pads 210 and the corresponding lower connection bumps 220. The conductive post 300 may be horizontally spaced apart from the semiconductor chip 200 (e.g., in the first direction D1). The conductive post 300 may be connected directly to a corresponding redistribution line 22 of the redistribution lines 22. The conductive post 300 may include or may be formed of a metal (e.g., copper).

In some embodiments, the lower structure 10 may further include a lower underfill layer 230 disposed between the first surface 20a of the redistribution substrate 20 and the semiconductor chip 200. The lower underfill layer 230 may fill a space between the lower connection bumps 220 and a space between corresponding redistribution lines 22 of the redistribution lines 22, between the first surface 20a of the redistribution substrate 20 and the semiconductor chip 200. The lower structure 10 may further include a molding layer 250 which is disposed on the first surface 20a of the redistribution substrate 20 and covers the semiconductor chip 200 and the conductive post 300. The molding layer 250 may cover the second surface 200b of the semiconductor chip 200 and may fill a space between the semiconductor chip 200 and the conductive post 300. The molding layer 250 may extend onto side surfaces of the lower underfill layer 230 and may be in contact with the first surface 20a of the redistribution substrate 20.

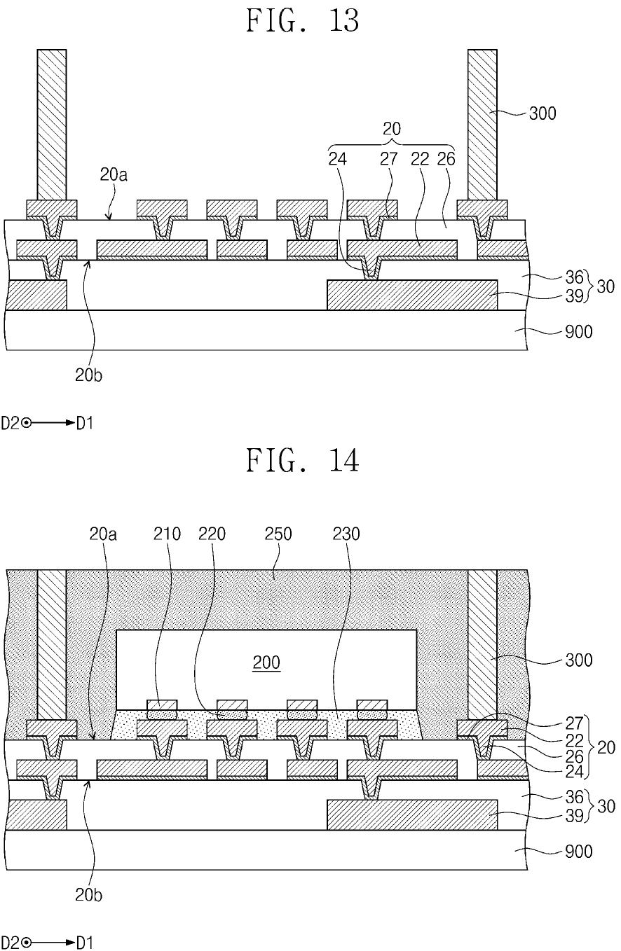

FIGS. 13 and 14 are cross-sectional views illustrating a method of manufacturing a semiconductor package according to some embodiments of the inventive concepts. Hereinafter, the descriptions to the same features as described with reference to FIG. 12 will be omitted for the purpose of ease and convenience in explanation.

Referring to FIG. 13, an under bump interconnection layer 30 and a redistribution substrate 20 may be sequentially formed on a carrier substrate 900. The under bump interconnection layer 30 and the redistribution substrate 20 may be formed by substantially the same method as the under bump interconnection layer 30 and the redistribution substrate 20 described with reference to FIG. 10. The redistribution substrate 20 may have a first surface 20a and a second surface 20b which are opposite to each other, and the second surface 20b of the redistribution substrate 20 may be adjacent to the under bump interconnection layer 30.

A conductive post 300 may be formed on the first surface 20a of the redistribution substrate 20. The conductive post 300 may be formed on a corresponding redistribution line 22 of the redistribution lines 22 and may be formed using, for example, an electroplating process. Even though not shown in the drawings, a conductive seed pattern may be formed between the conductive post 300 and the corresponding redistribution line 22, and the conductive post 300 may be formed by the electroplating process using the conductive seed pattern.

Referring to FIG. 14, a semiconductor chip 200 may be mounted on the first surface 20a of the redistribution substrate 20. Lower connection bumps 220 may be provided on chip pads 210 of the semiconductor chip 200, respectively, and the lower connection bumps 220 may be provided on corresponding redistribution lines 22 of the redistribution lines 22, respectively. A lower underfill layer 230 may be provided between the first surface 20a of the redistribution substrate 20 and the semiconductor chip 200 and may fill a space between the lower connection bumps 220 and between the corresponding redistribution lines 22. A molding layer 250 may be provided on the first surface 20a of the redistribution substrate 20 and may cover the semiconductor chip 200 and the conductive post 300.

Referring again to FIG. 12, the carrier substrate 900 may be removed. An electronic device 40 and a solder bump 50 may be provided on a surface of the under bump interconnection layer 30, which is exposed by the removal of the carrier substrate 900. The electronic device 40 may be disposed on a corresponding under bump pattern 39 of the under bump patterns 39, and a connection bump 42 may be disposed between the electronic device 40 and the corresponding under bump pattern 39. The solder bump 50 may be horizontally spaced apart from the electronic device 40 and may be disposed on a corresponding under bump pattern 39 of the under bump patterns 39.

A plurality of trenches 38 may be formed in the passivation layer 36 between the electronic device 40 and the solder bump 50. The plurality of trenches 38 may be formed by substantially the same method as the plurality of trenches 38 described with reference to FIGS. 6 to 8. An underfill layer 45 may be formed to fill a space between the electronic device 40 and a corresponding under bump pattern 39 and between the connection bumps 42 and may extend onto a top surface 36U of the passivation layer 36. The underfill layer 45 may fill at least a portion of the plurality of trenches 38.

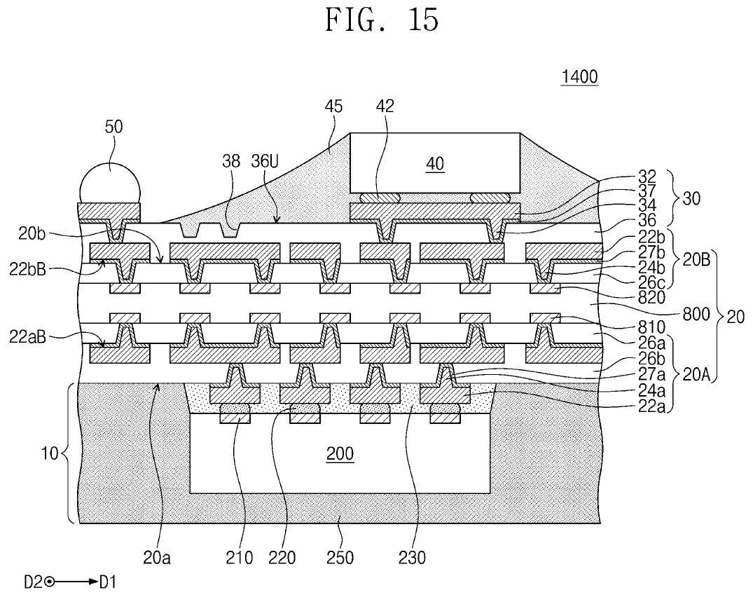

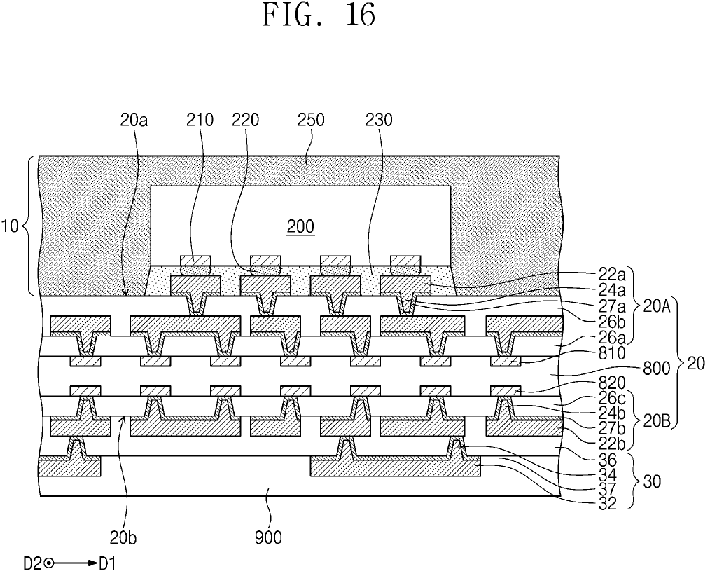

FIG. 15 is a cross-sectional view illustrating a semiconductor package according to some embodiments of the inventive concepts. Hereinafter, differences between the present embodiments and the above embodiments of FIG. 6 will be mainly described for the purpose of ease and convenience in explanation.

Referring to FIG. 15, a semiconductor package 1400 may include a lower structure 10, a redistribution substrate 20 on the lower structure 10, an under bump interconnection layer 30 on the redistribution substrate 20, an electronic device 40 and a solder bump 50 on the under bump interconnection layer 30, and an underfill layer 45 between the under bump interconnection layer 30 and the electronic device 40.

The redistribution substrate 20 may have a first surface 20a and a second surface 20b, which are opposite to each other. The redistribution substrate 20 may include a first redistribution layer 20A adjacent to the first surface 20a, a second redistribution layer 20B adjacent to the second surface 20b, and a core substrate 800 between the first redistribution layer 20A and the second redistribution layer 20B.

The first redistribution layer 20A may include first redistribution patterns 22a, 24a and 27a and first and second redistribution insulating layers 26a and 26b covering the first redistribution patterns 22a, 24a and 27a. The first redistribution patterns 22a, 24a and 27a may include first redistribution lines 22a spaced apart from each other in a direction perpendicular to the first surface 20a of the redistribution substrate 20, first redistribution contacts 24a connected to the first redistribution lines 22a, and first redistribution seed patterns 27a. Each of the first redistribution contacts 24a may extend from a bottom surface 22aB of a corresponding first redistribution line 22a of the first redistribution lines 22a toward the core substrate 800. Each of the first redistribution contacts 24a may be in contact with the corresponding first redistribution line 22a without an interface therebetween. Each of the first redistribution contacts 24a may have a width in a direction (e.g., the first direction D1) parallel to the first surface 20a of the redistribution substrate 20, and the width of each of the first redistribution contacts 24a may become progressively greater toward the bottom surface 22aB of the corresponding first redistribution line 22a. Each of the first redistribution seed patterns 27a may cover a bottom surface 22aB of a corresponding first redistribution line 22a of the first redistribution lines 22a and may extend along a side surface and a bottom surface of a corresponding first redistribution contact 24a of the first redistribution contacts 24a. The first redistribution lines 22a and the first redistribution contacts 24a may include or be formed of a metal material (e.g., copper), and the first redistribution seed patterns 27a may include or be formed of a conductive seed material (e.g., copper, titanium, and/or an alloy thereof).

The first redistribution insulating layer 26a may be adjacent to the core substrate 800, and the second redistribution insulating layer 26b may be adjacent to the first surface 20a of the redistribution substrate 20. The first redistribution insulating layer 26a and the second redistribution insulating layer 26b may cover the first redistribution patterns 22a, 24a and 27a, and some of the first redistribution lines 22a may be disposed on the second redistribution insulating layer 26b. The some of the first redistribution lines 22a may be disposed on the first surface 20a of the redistribution substrate 20. The first redistribution insulating layer 26a and the second redistribution insulating layer 26b may include or be formed of the same material and may include or be formed of, for example, a photosensitive polymer.

The second redistribution layer 20B may include second redistribution patterns 22b, 24b and 27b and a third redistribution insulating layer 26c covering the second redistribution patterns 22b, 24b and 27b. The second redistribution patterns 22b, 24b and 27b may include second redistribution lines 22b spaced apart from each other in the direction perpendicular to the first surface 20a of the redistribution substrate 20, second redistribution contacts 24b connected to the second redistribution lines 22b, and second redistribution seed patterns 27b. Each of the second redistribution contacts 24b may extend from a bottom surface 22bB of a corresponding second redistribution line 22b of the second redistribution lines 22b toward the core substrate 800. Each of the second redistribution contacts 24b may be in contact with the corresponding second redistribution line 22b without an interface therebetween. Each of the second redistribution contacts 24b may have a width in the direction (e.g., the first direction D1) parallel to the first surface 20a of the redistribution substrate 20, and the width of each of the second redistribution contacts 24b may become progressively greater toward the bottom surface 22bB of the corresponding second redistribution line 22b. Each of the second redistribution seed patterns 27b may cover a bottom surface 22bB of a corresponding second redistribution line 22b of the second redistribution lines 22b and may extend along a side surface and a bottom surface of a corresponding second redistribution contact 24b of the second redistribution contacts 24b. The second redistribution lines 22b and the second redistribution contacts 24b may include or be formed of a metal material (e.g., copper), and the second redistribution seed patterns 27b may include or be formed of a conductive seed material (e.g., copper, titanium, and/or an alloy thereof).

The third redistribution insulating layer 26c may be disposed on the core substrate 800 and may cover the second redistribution patterns 22b, 24b and 27b. Some of the second redistribution lines 22b may be disposed on the third redistribution insulating layer 26c. The some of the second redistribution lines 22b may be disposed on the second surface 20b of the redistribution substrate 20. The third redistribution insulating layer 26c may include or be formed of the same material as the first redistribution insulating layer 26a and the second redistribution insulating layer 26b and may include or be formed of, for example, a photosensitive polymer.

First substrate pads 810 of the core substrate 800 may be connected to corresponding first redistribution patterns (e.g., corresponding first redistribution contacts 24a) of the first redistribution patterns 22a, 24a and 27a of the first redistribution layer 20A. Second substrate pads 820 of the core substrate 800 may be connected to corresponding second redistribution patterns (e.g., corresponding second redistribution contacts 24b) of the second redistribution patterns 22b, 24b and 27b of the second redistribution layer 20B. The first substrate pads 810 and the second substrate pads 820 may be electrically connected to each other through internal interconnection lines of the core substrate 800. The core substrate 800 may be, for example, a printed circuit board. The first redistribution layer 20A and the second redistribution layer 20B may be electrically connected to each other through the core substrate 800.

The lower structure 10 may be disposed on the first surface 20a of the redistribution substrate 20, and the under bump interconnection layer 30 may be disposed on the second surface 20b of the redistribution substrate 20.

The under bump interconnection layer 30 may include conductive patterns 32, 34 and 37, and a passivation layer 36 covering the conductive patterns 32, 34 and 37. In some embodiments, the passivation layer 36 may include or be formed of a solder resist material. The conductive patterns 32, 34 and 37 may be substantially the same as the conductive patterns 32, 34 and 37 described with reference to FIG. 6. The conductive patterns 32, 34 and 37 may be electrically connected to corresponding second redistribution patterns (e.g., corresponding second redistribution lines 22b) of the second redistribution patterns 22b, 24b and 27b of the second redistribution layer 20B.

The electronic device 40, the solder bump 50 and the underfill layer 45 may be disposed on the under bump interconnection layer 30. The electronic device 40, the solder bump 50 and the underfill layer 45 may be substantially the same as the electronic device 40, the solder bump 50 and the underfill layer 45, described with reference to FIG. 6. The electronic device 40 and the solder bump 50 may be electrically connected to the second redistribution layer 20B through the conductive patterns 32, 34 and 37. The passivation layer 36 may include a plurality of trenches 38 disposed between the electronic device 40 and the solder bump 50. The plurality of trenches 38 may be substantially the same as the plurality of trenches 38 described with reference to FIGS. 1 to 5.

The lower structure 10 may include a semiconductor chip 200 mounted on the first surface 20a of the redistribution substrate 20, lower connection bumps 220 disposed on chip pads 210 of the semiconductor chip 200, respectively, a lower underfill layer 230 disposed between the first surface 20a of the redistribution substrate 20 and the semiconductor chip 200, and a molding layer 250 disposed on the first surface 20a of the redistribution substrate 20 and covering the semiconductor chip 200. The chip pads 210 of the semiconductor chip 200 may be electrically connected to corresponding first redistribution patterns (e.g., corresponding first redistribution lines 22a) of the first redistribution patterns 22a, 24a and 27a of the first redistribution layer 20A through the lower connection bumps 220. The semiconductor chip 200 may be electrically connected to the first redistribution layer 20A through the chip pads 210 and the lower connection bumps 220. The lower underfill layer 230 may fill a space between the lower connection bumps 220 and may fill a space between corresponding first redistribution lines 22a of the first redistribution lines 22a. The molding layer 250 may cover the semiconductor chip 200 and may extend onto side surfaces of the lower underfill layer 230. The molding layer 250 may be in contact with the first surface 20a of the redistribution substrate 20.

FIG. 16 is a cross-sectional view illustrating a method of manufacturing a semiconductor package according to some embodiments of the inventive concepts. Hereinafter, the descriptions to the same features as described with reference to FIG. 15 will be omitted for the purpose of ease and convenience in explanation.

Referring to FIG. 16, a first redistribution layer 20A may be formed on one surface of a core substrate 800, and a second redistribution layer 20B may be formed on another surface of the core substrate 800.

For example, the formation of the first redistribution layer 20A may include forming a first redistribution insulating layer 26a on the one surface of the core substrate 800, forming first redistribution contact holes penetrating the first redistribution insulating layer 26a, forming a first redistribution seed pattern 27a which fills a portion of each of the first redistribution contact holes and extends onto one surface of the first redistribution insulating layer 26a, and performing an electroplating process using the first redistribution seed pattern 27a to form a first redistribution contact 24a and a first redistribution line 22a. The formation of the first redistribution layer 20A may further include forming a second redistribution insulating layer 26b on the first redistribution insulating layer 26a, and forming additional first redistribution seed patterns 27a, additional first redistribution contacts 24a and additional first redistribution lines 22a on the second redistribution insulating layer 26b. The additional first redistribution seed patterns 27a, the additional first redistribution contacts 24a and the additional first redistribution lines 22a may be formed by substantially the same method as the first redistribution seed pattern 27a, the first redistribution contact 24a and the first redistribution line 22a.

For example, the formation of the second redistribution layer 20B may include forming a third redistribution insulating layer 26c on the other surface of the core substrate 800, forming second redistribution contact holes penetrating the third redistribution insulating layer 26c, forming a second redistribution seed pattern 27b which fills a portion of each of the second redistribution contact holes and extends onto one surface of the third redistribution insulating layer 26c, and performing an electroplating process using the second redistribution seed pattern 27b to form a second redistribution contact 24b and a second redistribution line 22b. The first redistribution layer 20A, the core substrate 800 and the second redistribution layer 20B may constitute a redistribution substrate 20.

An under bump interconnection layer 30 may be formed on the second redistribution layer 20B. For example, the formation of the under bump interconnection layer 30 may include forming a passivation layer 36 on the third redistribution insulating layer 26c, forming conductive contact holes penetrating the passivation layer 36, forming a conductive seed pattern 37 which fills a portion of each of the conductive contact holes and extends onto one surface of the passivation layer 36, and performing an electroplating process using the conductive seed pattern 37 to form a conductive contact 34 and a conductive pad 32. The redistribution substrate 20 on which the under bump interconnection layer 30 is formed may be provided on a carrier substrate 900.

A semiconductor chip 200 may be mounted on the first redistribution layer 20A. Lower connection bumps 220 may be provided on chip pads 210 of the semiconductor chip 200, respectively, and the lower connection bumps 220 may be provided on corresponding first redistribution lines 22a of the first redistribution lines 22a, respectively. A lower underfill layer 230 may be provided between the first redistribution layer 20A and the semiconductor chip 200 and may fill a space between the lower connection bumps 220 and between the corresponding first redistribution lines 22a. A molding layer 250 may be provided on the first redistribution layer 20A and may cover the semiconductor chip 200.

Referring again to FIG. 15, the carrier substrate 900 may be removed. An electronic device 40 and a solder bump 50 may be provided on a surface of the under bump interconnection layer 30, which is exposed by the removal of the carrier substrate 900. A plurality of trenches 38 may be formed in the passivation layer 36 between the electronic device 40 and the solder bump 50. The plurality of trenches 38 may be formed by substantially the same method as the plurality of trenches 38 described with reference to FIGS. 6 to 8. An underfill layer 45 may be formed to fill a space between the electronic device 40 and a corresponding conductive pad 32 and between connection bumps 42 and to extend onto a top surface 36U of the passivation layer 36. The underfill layer 45 may fill at least a portion of the plurality of trenches 38.

According to the inventive concepts, the plurality of trenches may be disposed between the electronic device and the solder bump to inhibit the flow of the underfill layer. The plurality of trenches may be formed to effectively inhibit the flow of the underfill layer in a limited area between the electronic device and the solder bump. In addition, a contact interface between the passivation layer and the underfill layer may be increased by the plurality of trenches, and thus a delamination phenomenon of the underfill layer may be minimized. As a result, it is possible to provide small and highly integrated semiconductor packages with excellent reliability, and the methods of manufacturing the same.

While example embodiments of the inventive concept have been particularly shown and described, it will be understood by one of ordinary skill in the art that variations in form and detail may be made therein without departing from the spirit and scope of the attached claims.

1. A semiconductor package comprising:
a redistribution substrate having a first surface and a second surface which are opposite to each other;
a semiconductor chip mounted on the first surface of the redistribution substrate;
an under bump interconnection layer on the second surface of the redistribution substrate;
an electronic device mounted on the under bump interconnection layer; and
a solder bump disposed on the under bump interconnection layer and horizontally spaced apart from the electronic device,
wherein the under bump interconnection layer comprises: conductive patterns respectively connected to the electronic device and the solder bump; and a passivation layer covering the conductive patterns, and
wherein the passivation layer includes a plurality of trenches disposed between the electronic device and the solder bump.

2. The semiconductor package of claim 1, wherein each of the plurality of trenches extends from a first surface of the passivation layer into the passivation layer and toward a second surface of the passivation layer facing the redistribution substrate.

3. The semiconductor package of claim 2, further comprising:
an underfill layer between the under bump interconnection layer and the electronic device,
wherein the underfill layer extends onto the first surface of the passivation layer and fills at least a portion of the plurality of trenches.

4. The semiconductor package of claim 1, wherein the plurality of trenches includes: a first trench closest to the solder bump among the plurality of trenches; and a second trench farthest from the solder bump among the plurality of trenches,
wherein the second trench is closer to the solder bump than it is to the electronic device, and the first trench is disposed between the solder bump and the second trench.

5. The semiconductor package of claim 1, wherein the electronic device is spaced apart from the solder bump by a first distance,
wherein the plurality of trenches is located within a second distance from the solder bump, and the second distance is half of the first distance.

6. The semiconductor package of claim 1, wherein each trench of the plurality of trenches has a maximum width in a direction parallel to a top surface of the passivation layer, and
wherein the width of each of the plurality of trenches is a width in a range from 25 µm to 100 µm.

7. The semiconductor package of claim 6, wherein a distance between a pair of adjacent trenches of the plurality of trenches is in a range from 25 µm to 100 µm.

8. The semiconductor package of claim 1, wherein the solder bump is one of a plurality of solder bumps,
wherein the solder bumps are arranged to surround the electronic device when viewed in a plan view, and
wherein the plurality of trenches is disposed between the plurality of solder bumps and the electronic device.

9. The semiconductor package of claim 8, wherein the electronic device has a first side surface and a second side surface, which are opposite to each other in a first direction parallel to a top surface of the passivation layer,
wherein the plurality of trenches includes: a first group of trenches disposed between the first side surface of the electronic device and corresponding solder bumps of the plurality of solder bumps; and a second group of trenches disposed between the second side surface of the electronic device and corresponding solder bumps of the plurality of solder bumps, and
wherein each of the first group of trenches and the second group of trenches has a line shape extending in a second direction which is parallel to the top surface of the passivation layer and intersects the first direction.

10. The semiconductor package of claim 9, wherein the electronic device has a third side surface and a fourth side surface, which are opposite to each other in the second direction,
wherein the plurality of trenches includes: a third group of trenches disposed between the third side surface of the electronic device and corresponding solder bumps of the plurality of solder bumps; and a fourth group of trenches disposed between the fourth side surface of the electronic device and corresponding solder bumps of the plurality of solder bumps, and
wherein the third group of trenches and the fourth group of trenches have line shapes extending in the first direction.

11. The semiconductor package of claim 8, wherein each of the plurality of trenches has a ring shape surrounding the electronic device, when viewed in a plan view.

12. The semiconductor package of claim 1, further comprising:
a base substrate disposed on the first surface of the redistribution substrate, the base substrate including a substrate hole penetrating the base substrate; and
a conductive structure penetrating the base substrate,
wherein the semiconductor chip is disposed in the substrate hole of the base substrate, and
wherein the semiconductor chip and the conductive structure are electrically connected to respective redistribution patterns in the redistribution substrate.

13. The semiconductor package of claim 1, further comprising:
a conductive post disposed on the first surface of the redistribution substrate and horizontally spaced apart from the semiconductor chip; and
a molding layer disposed on the first surface of the redistribution substrate and covering the semiconductor chip and the conductive post,
wherein the semiconductor chip and the conductive post are electrically connected to redistribution patterns in the redistribution substrate.

14. The semiconductor package of claim 1, wherein the redistribution substrate comprises:
a first redistribution layer adjacent to the first surface of the redistribution substrate;
a second redistribution layer adjacent to the second surface of the redistribution substrate; and
a core substrate between the first redistribution layer and the second redistribution layer,
wherein the core substrate electrically connects the first redistribution layer and the second redistribution layer to each other.

15. The semiconductor package of claim 14, wherein the semiconductor chip is electrically connected to first redistribution patterns in the first redistribution layer, and
wherein the conductive patterns in the under bump interconnection layer are electrically connected to second redistribution patterns in the second redistribution layer.

16. A semiconductor package comprising:
an under bump interconnection layer;
an electronic device mounted on the under bump interconnection layer; and
a plurality of solder bumps arranged to surround the electronic device on the under bump interconnection layer,
wherein the under bump interconnection layer comprises: conductive patterns respectively connected to the electronic device and the plurality of solder bumps; and a passivation layer covering the conductive patterns,
wherein the electronic device has a first side surface and a second side surface, which are opposite to each other in a first direction parallel to a top surface of the passivation layer,
wherein the passivation layer includes: a first group of trenches disposed between the first side surface of the electronic device and corresponding solder bumps of the plurality of solder bumps; and a second group of trenches disposed between the second side surface of the electronic device and corresponding solder bumps of the plurality of solder bumps, and
wherein each trench of the first group of trenches and the second group of trenches has a line shape extending in a second direction which is parallel to the top surface of the passivation layer and intersects the first direction.

17. The semiconductor package of claim 16, wherein the electronic device has a third side surface and a fourth side surface, which are opposite to each other in the second direction,
wherein the passivation layer includes: a third group of trenches disposed between the third side surface of the electronic device and corresponding solder bumps of the plurality of solder bumps; and a fourth group of trenches disposed between the fourth side surface of the electronic device and corresponding solder bumps of the plurality of solder bumps, and
wherein each trench of the third group of trenches and the fourth group of trenches has a line shape extending in the first direction.

18. The semiconductor package of claim 17, wherein one trench of the first group of trenches, one trench of the second group of trenches, one trench of the third group of trenches and one trench of the fourth group of trenches are connected to each other to constitute a continuous ring shape surrounding the first to fourth side surfaces of the electronic device.

19. A semiconductor package comprising:
an under bump interconnection layer;
an electronic device mounted on the under bump interconnection layer; and
a solder bump disposed on the under bump interconnection layer and horizontally spaced apart from the electronic device,
wherein the under bump interconnection layer comprises: conductive patterns connected to the electronic device and the solder bump; and a passivation layer covering the conductive patterns,
wherein the passivation layer includes a plurality of trenches disposed between the electronic device and the solder bump,
wherein the electronic device is spaced apart from the solder bump by a first distance,
wherein the plurality of trenches is located within a second distance from the solder bump, and the second distance is half of the first distance.

20. The semiconductor package of claim 19, wherein each of the plurality of trenches has a width in a direction parallel to a top surface of the passivation layer, and
wherein the width of each of the plurality of trenches is a width in a range from 25 µm to 100 µm.

21-22. (canceled)
